(19) United States
(12) Patent Application Publication
(10) Pub. No.: US 2023/0422531 A1
(43) Pub. Date: Dec. 28, 2023

(54) PHOTOELECTRIC CONVERSION ELEMENT AND METHOD FOR MANUFACTURING THE SAME

(71) Applicants: KABUSHIKI KAISHA TOSHIBA, Tokyo (JP); TOSHIBA ENERGY SYSTEMS & SOLUTIONS CORPORATION, Kawasaki-shi Kanagawa (JP)

(72) Inventors: Takeshi GOTANDA, Yokohama Kanagawa (JP); Tomohiro TOBARI, Yokohama Kanagawa (JP); Yutaka SAITA, Yokohama Kanagawa (JP); Katsuya YAMASHITA, Kawasaki Kanagawa (JP); Kenji FUJINAGA, Yokohama Kanagawa (JP); Miyuki SHIOKAWA, Kawasaki Kanagawa (JP)

(73) Assignees: KABUSHIKI KAISHA TOSHIBA, Tokyo (JP); TOSHIBA ENERGY SYSTEMS & SOLUTIONS CORPORATION, Kawasaki-shi Kanagawa (JP)

(21) Appl. No.: 18/253,030

(22) PCT Filed: Jul. 7, 2021
(86) PCT No.: PCT/JP2021/025717

§ 371 Date: May 15, 2023

(30) Foreign Application Priority Data
Nov. 16, 2020 (WO) PCT/JP2020/042620

(51) Int. Cl. H10K 30/50; H10K 30/82; H10K 85/50; H10K 30/30; H10K 71/40

(52) U.S. Cl. CPC H10K 30/50; H10K 30/82; H10K 85/50; H10K 30/353; H10K 71/441

(57) ABSTRACT

Provided are a photoelectric conversion element that can generate power with high efficiency and has high durability, and a method for manufacturing the same.

A photoelectric conversion element according to an embodiment includes
a first electrode,
an active layer having a perovskite structure containing a halogen ion, and
a second electrode having light transmissivity,
in which a Warburg coefficient of the active layer measured by an AC impedance spectroscopy method is specified. The element can be manufactured by applying a solution containing a precursor of the perovskite structure and then performing appropriate annealing treatment or gas blowing.

### CROSS REFERENCE TO RELATED APPLICATIONS

This application is based upon and claims the benefit of priority from the prior International Patent Applications PCT/JP2020/042620, filed on Nov. 16, 2020, and PCT/JP2021/025717, filed on Jul. 8, 2021, the entire contents of which are incorporated herein by reference.

### FIELD

Embodiments of the present invention relate to a photoelectric conversion element having high efficiency and high durability, and a method for manufacturing the same.

### BACKGROUND

Conventionally, a semiconductor element such as a photoelectric conversion element or a light-emitting element has been generally manufactured by a relatively complicated method such as a vapor deposition method. However, when the semiconductor element can be produced by a coating method or a printing method, the semiconductor element can be easily produced at a lower cost than a general vapor deposition method, and thus such a method is being sought. Meanwhile, a semiconductor element such as a solar cell, a sensor, and a light-emitting element using a material including an organic material or a combination of an organic material and an inorganic material has been actively researched and developed. These researches aim to find an element having high photoelectric conversion efficiency or high light emission efficiency. Furthermore, as an object of such research, a perovskite semiconductor can be manufactured by a coating method, and high efficiency can be expected, and thus, the perovskite semiconductor has recently attracted attention.

### BRIEF DESCRIPTION OF THE DRAWINGS

FIG. 1 is a schematic diagram illustrating a structure of a photoelectric conversion element manufactured according to an embodiment.

FIG. 2 is a schematic view illustrating a structure of a manufacturing apparatus that can be used for manufacturing the photoelectric conversion element according to the embodiment.

FIG. 3 is a cross-sectional view of a gas blowing nozzle that can be used for manufacturing the photoelectric conversion element according to the embodiment.

FIG. 4 is a graph illustrating a relationship between a Warburg coefficient and a maintenance rate.

### DETAILED DESCRIPTION

Embodiments will now be explained with reference to the accompanying drawings.

According to an embodiment, there is provided a photoelectric conversion element including:

a first electrode;

an active layer having a perovskite structure containing a halogen ion; and

a second electrode having light transmissivity,

in which a Warburg coefficient calculated from a Warburg impedance W (Ωs^{-1/2}) determined when an impedance spectrum measured by an AC impedance spectroscopy method fitted with an equivalent circuit represented by the following Equation (1) is 25,000 or more.

In addition, according to another embodiment, there is provided a method for manufacturing the photoelectric conversion element, the method including a step of forming the active layer by forming a perovskite structure by subjecting a coating film of a solution containing a precursor of the perovskite structure to an annealing treatment or a gas blowing treatment.

In an embodiment, a semiconductor element means both a photoelectric conversion element such as a solar cell or a sensor and a light-emitting element. The both elements are different in whether an active layer functions as a photoelectric conversion layer or as a light emitting layer, but are the same in basic structure.

Hereinafter, constituent members of the semiconductor element according to the embodiment will be described using a solar cell as an example, but can also be applied to a photoelectric conversion element having a common structure.

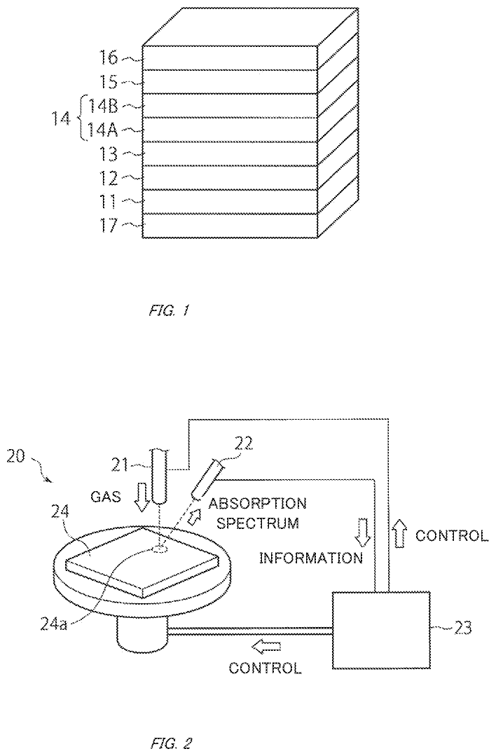

The photoelectric conversion element according to the embodiment essentially includes a first electrode, an active layer, and a second electrode, and FIG. 1 is a schematic view illustrating an example of a configuration of a solar cell 10 which is an aspect of the photoelectric conversion element according to the embodiment. In the element illustrated here, a first electrode 11, a first buffer layer 12, an active layer (photoelectric conversion layer) 13, a second buffer layer 14, a barrier layer 15, and a second electrode 16 are laminated on a substrate 17.

The first electrode 11 and the second electrode 16 serve as an anode or a cathode, and electricity flows therethrough. The active layer 13 is a material that is excited by light incident through the substrate 17, the first electrode 11, and the first buffer layer 12, or the second electrode 16 and the second buffer layer 14 to generate electrons or holes in the first electrode 11 and the second electrode 16. Further, the active layer is a material that generates light after electrons and holes are injected from the first electrode 11 and the second electrode 16.

In FIG. 1, the first buffer layer 12 and the second buffer layer 14 are layers existing between the active layer and the first electrode or the second electrode. In FIG. 1, the first buffer layer and the second buffer layer are disposed on both surfaces of the active layer, respectively, but may have a so-called back contact type structure in which both the first electrode 11 and the first buffer layer 12, and the second buffer layer 14 and the second electrode 16 are disposed apart from each other on one side surface of the active layer 13.

The second buffer layer may have a laminated structure of two or more layers. FIG. 1 discloses a structure in which the second buffer layer is composed of two layers 14A and 148, but for example, an active layer-side buffer layer 14A may be a layer containing an organic semiconductor, and a second electrode-side buffer layer 148 may be a layer containing a metal oxide.

The active layer-side buffer layer 14A and the second electrode-side buffer layer 148 are materials capable of transporting electrons or holes. The second electrode-side buffer layer 148 has a function of protecting the active layer 13, the first buffer layer 12, and the active layer-side buffer layer 14A from damage at the time of forming the barrier layer 15.

The barrier layer 15 has an effect of suppressing deterioration of the second electrode (to be described in detail later). In order to sufficiently exhibit such an effect, the barrier layer 15 is preferably a denser layer than the second electrode-side buffer layer 14B.

Hereinafter, each layer constituting the semiconductor element according to the embodiment will be described.

### Substrate 17

The substrate 17 is for supporting other constituent members at least in the manufacturing process. This substrate may be used only during the manufacture of the solar cell and removed after or during the manufacture. It is preferable that an electrode can be formed on a surface of the substrate 17. Therefore, it is preferable that the substrate is hardly altered by heat applied at the time of forming the electrode or an organic solvent in contact with the electrode. Examples of a material of the substrate 17 include (i) an inorganic material such as alkali-free glass and quartz glass, (ii) plastic such as polyethylene, polyethylene terephthalate (PET), polyethylene naphthalate (PEN), polyimide, polyimide, polyamideimide, a liquid crystal polymer, and a cycloolefin polymer, an organic material such as a polymer film, and (iii) a metal material such as stainless steel (SUS), aluminum, titanium, and silicon.

The material of the substrate 17 is appropriately selected according to the structure of the solar cell of interest. When the substrate is to be removed after or during the manufacture of the solar cell, the substrate may be transparent or opaque. In addition, when the photoelectric conversion element includes the substrate and light enters from the surface of the substrate 17, a transparent substrate is used. In addition, when the substrate 17 is on a side opposite to a light incident surface of the photoelectric conversion dement, an opaque substrate can also be used.

A thickness of the substrate is not particularly limited as long as the substrate has sufficient strength to support the other constituent members.

In a case where the substrate 17 is disposed on the light incident surface side, for example, an antireflection film having a moth-eye structure can be installed on the light incident surface of the substrate. With such a structure, it is possible to efficiently take in light and improve energy conversion efficiency of the celli The moth-eye structure has a structure having a regular protrusion arrangement of about 100 nm on the surface, and a refractive index in a thickness direction is continuously changed by this protrusion structure. Therefore, by mediating a non-reflective film, a discontinuous change surface of a refractive index is eliminated, so that light reflection is reduced, and cell efficiency is improved.

The substrate may be made of a single material or a laminated structure made of two or more kinds of materials. Furthermore, for example, a function of a photoelectric conversion dement may be exhibited by combining with another semiconductor element. Specifically, the solar cell according to the embodiment may be formed on an already completed silicon solar cell, a compound solar cell, or the like to form a tandem solar cell. In this case, an equivalent circuit is preferably a parallel circuit. Further, the first electrode and the like may be shared with the silicon solar cell. In this case, the equivalent circuit is preferably a series circuit.

### First Electrode and Second Electrode

The first electrode 11 can be selected from any conventionally known electrodes as long as the electrodes have conductivity. In the present embodiment, the first electrode is disposed on the light incident surface side. Therefore, the material of the first electrode should be selected from transparent or translucent conductive materials Examples of the transparent or translucent electrode material include a conductive metal oxide film and a translucent metal thin film. The first electrode 11 may have a structure in which a plurality of materials are laminated.

Specifically, preferably, a film (MESA or the like) produced using a conductive glass is used such as: indium oxide, zinc oxide, and tin oxide; indium-soot oxide (ITO), indium-zinc-oxide (IZO), fluorine-doped tin oxide (FTC)), and indium zinc-oxide, which are composites of indium oxide, zinc oxide and tin oxide; and aluminum, gold, platinum, silver, copper. In particular, a metal oxide such as ITO, IZO, or FTO is preferable for the first electrode. The transparent electrode made of such a metal oxide can be formed by a generally known method. Specifically, the transparent electrode is formed by sputtering in an atmosphere rich in a reaction gas such as oxygen. In such a case, a content of the reaction gas such as oxygen contained in the atmosphere is 0.5% or more, and as a result, a metal oxide film having high crystallinity and high conductivity is formed.

A thickness of the first electrode is preferably 30 to 300 nm when the material of the electrode is ITO. When the thickness of the electrode is less than 30 nm, conductivity tends to decrease and resistance tends to increase. An increase in resistance may cause a decrease in photoelectric conversion efficiency. Meanwhile, when the thickness of the electrode is larger than 300 nm, flexibility of the ITO film tends to decrease. As a result, when the film thickness is large, cracking may occur when stress acts. A sheet resistance of the electrode is preferably as low as possible, and is preferably 10 Ω/sq, or less. The electrode may have a single-layer structure or a multilayer structure in which layers composed of materials having different work functions are laminated.

When the first electrode is formed adjacent to an electron transport layer, a material having a low work function is preferably used as the electrode material. Examples of the material having a low work function include an alkali metal and an alkaline earth metal. Specific examples thereof include lithium, indium, aluminum, calcium, magnesium, samarium, terbium, ytterbium, zirconium, sodium, potassium, rubidium, cesium, barium, and an alloy thereof. In addition, an alloy of a metal selected from the above-described materials having a low work function and a metal having a relatively high work function selected from gold, silver, platinum, copper, manganese, titanium, cobalt, nickel, tungsten, tin, and the like may be used. Examples of the alloy that can be used for the electrode material include a lithium-aluminum alloy, a lithium-magnesium alloy, a lithium-indium alloy, a magnesium-silver alloy, a calcium-indium alloy, a magnesium-aluminum alloy, an indium-silver alloy, a calcium-aluminum alloy, or the like. When such a metal material is used, the thickness of the electrode is preferably 1 nm to 500 nm, and more preferably 10 nm to 300 nm. When the film thickness is thinner than the above range, the resistance becomes too large, and the generated charge may not be sufficiently transmitted to an external circuit. When the film thickness is large, it takes a long time to form the electrode, so that the temperature of the material increases, and other materials are damaged, and the performance may be deteriorated. Furthermore, since a large amount of material is used, an occupancy time of a film forming apparatus becomes long, which may lead to an increase in cost.

An organic material can also be used as the first electrode material. For example, a conductive polymer compound such as polyethylene dioxythiophene (hereinafter, sometimes referred to as PEDOT) is preferable. Such a conductive polymer compound is commercially available, and examples thereof include Clevios P H 500, Clevios P H, Clevios P VP Al 4083, and Clevios HIL 1,1 (all of them are trade names, manufactured by Starck, Inc.). The work function (or ionizing potential) of PEDOT is 4.4 eV, but another material can be combined therewith to adjust the work function of the electrode. For example, by mixing PEDOT with polystyrene sulfonate (hereinafter, sometimes referred to as PSS), the work function can be prepared in the range of 5.0 to 5.8 eV. However, in a layer formed of a combination of the conductive polymer compound and another material, a ratio of the conductive polymer compound relatively decreases, and thus carrier transportability may be deteriorated. Therefore, the thickness of the electrode in such a case is preferably 50 nm or less, and more preferably 15 nm or less. When the ratio of the conductive polymer compound relatively decreases, a coating liquid for a perovskite layer is easily repelled due to the influence of surface energy, and thus, pinholes tend to be easily generated in the perovskite layer. In such a case, it is preferable to complete drying of a solvent before the coating liquid is repelled by blowing nitrogen gas or the like. As the conductive polymer compound, polypyrrole, polythiophene, and polyaniline are preferable.

In the embodiment, the second electrode is preferably made of a uniform metal layer. Here, the uniform metal layer refers to a layer having a continuous coating structure that does not have a structure such as an opening for improving light transmissivity. Therefore, a structure having a plurality of through holes in the metal thin film, a woven fabric-like structure of metal fibers, a comb-like structure in which metal thin wires are combined, and the like are not included in the embodiments. The thickness of the second metal electrode is preferably 10 to 60 nm. Thus, when the surface of the second electrode is irradiated with light, the light can be transmitted to the second buffer layer or the active layer. When the surface of the first electrode is irradiated with light, light that is not absorbed by the active layer but transmitted to the second electrode can be reflected and absorbed again by the active layer. At this time, in the structure having the through hole, all the light cannot be reflected and absorbed again by the active layer.

As a material of the second electrode, aluminum, silver, gold, platinum, copper, or the like is used, but aluminum or silver is preferable. In particular, aluminum is preferably used from the viewpoint of light reflectivity and cost.

### Active Layer

The active layer (photoelectric conversion layer) 13 formed by the method of the embodiment has a perovskite structure in at least a part thereof. The perovskite structure is one of the crystal structures, and refers to the same crystal structure as the perovskite. Typically, the perovskite structure is composed of ions A, B, and X, and may take the perovskite structure when the ion B is smaller than the ion A. A chemical composition of this crystal structure can be represented by the following general Equation (1).

ABX₃ (1)

Here, A may be a primary ammonium ion. Specific examples thereof include CH₃NH₃⁺, C₂H₅NH₃⁺, C₃H₇NH₃⁺, C₄H₉NH₃⁺, and HC(NH₂)₂⁺, and CH₃NH₃⁺ is preferable, but are not limited thereto. In addition, as A, Cs and 1,1,1-trifluoro-ethylammonium iodide (FEAI) are also preferable, but A is not limited thereto. B is a divalent metal ion, and is preferably Pb²⁺ or Sn²⁺, but is not limited thereto, X is preferably a halogen ion. For example, X is selected from F⁻, Cl⁻, Br⁻, I⁻, and At⁻, and is preferred but not limited to Cl⁻, Br⁻, or I⁻. Each of the materials constituting the ions A, B, or X may be a single material or a mixture. The constituent ions can function without necessarily matching with the stoichiometric ratio of ABX₃.

This crystal structure has a unit lattice such as a cubic crystal, a tetragonal crystal, or an orthorhombic crystal, and A is arranged at each vertex, B is arranged at a body center, and X is arranged at each face center of the cubic crystal with B as the center. In this crystal structure, an octahedron composed of one B and six X contained in the unit lattice is easily distorted by interaction with A, and phase transitions to a symmetric crystal. It is presumed that this phase transition dramatically changes the physical properties of the crystal, and electrons or holes are released outside the crystal, resulting in power generation.

When the thickness of the active layer increases, a light absorption amount increases and a short circuit current density (Jsc) increases, but loss due to deactivation tends to increase as the carrier transport distance increases. Therefore, there is an optimum thickness for obtaining the maximum efficiency, and the thickness is preferably 30 nm to 1000 nm, and more preferably 60 to 600 nm.

For example, by individually adjusting the thickness of the active layer, the element according to the embodiment and other general elements can be adjusted to have the same conversion efficiency under a sunlight irradiation condition. However, since a film quality is different, the element according to the embodiment can realize higher conversion efficiency than a general element under low illuminance conditions such as 200 lux.

In the photoelectric conversion element according to the embodiment, the active layer has a specific Warburg coefficient. The Warburg coefficient of the active layer can be analyzed by an AC impedance spectroscopy method in the dark.

The AC impedance spectroscopy is a measurement method of applying an alternating current to an element and observing a response to a change in an electric field. This is a method of capturing different conductive components. The measurement result of the semiconductor element having the perovskite structure in the active layer can be fitted by an equivalent circuit of Equation 1. At this time, when the Warburg coefficient a is 25,000 or more, preferably 1 million, high durability is obtained. The fitting is performed by a method including a least squares method using R₁, R₂, R₃, C₁, and C₂ as variables. The fitting is performed using a numerical value close to a value considered from an actual value as an initial value. When an appropriate initial value is not set, a solution may not be obtained due to convergence or divergence to a fitting result that does not represent a feature of the actual value. The initial value is preferably selected from a range of ±2 times the value considered from an experimental value to start the fitting.

From a second law of diffusion of Fick, there is the following Equation (2):

W=σω^{-1/2}(1−j) (2)
(where:
W is a Warburg impedance,
σ is a Warburg coefficient;
ω is an angular frequency,
j is an imaginary part), and
the Warburg coefficient can be determined from the Warburg impedance W determined by fitting. This Warburg coefficient is considered to correspond to ease of movement of ions, and it can be said that as the Warburg coefficient is larger, ions are less likely to move.

Here, series resistances R₁, R₂, and R₃ each independently become 1 to 10 Ω. In addition, capacitances C₁ and C₂ each independently become 0,1 to 1 μF.

A semiconductor layer containing the perovskite semiconductor contains halogen ions, and when the halogen ions diffuse to another layer, for example, a metal electrode, the metal ions are easily eroded. Therefore, when the halogen ions are easily diffused, the durability of the element is easily deteriorated. It is considered that when many lattice defects and the like are present in the perovskite structure, diffusion of halogen ions increases, but the present inventors have studied a relationship between the ease of diffusion of halogen ions and the Warburg coefficient, and have found that a photoelectric conversion element including an active layer having a specific Warburg coefficient has excellent durability. That is, when the Warburg coefficient is large, diffusion of halogen ions is reduced, and as a result, durability of the element is increased.

In embodiments, the Warburg coefficient relates to the active layer and not to the element. That is, an object to be analyzed in the AC impedance spectroscopy is a simplified element including the active layer included in the photoelectric conversion element of the embodiment and two electrodes for constituting a basic element.

Such an active layer can be formed, for example, by forming the perovskite structure by annealing a coating film containing a precursor of the perovskite structure under appropriate annealing conditions or by blowing gas (to be described in detail later).

### First Buffer Layer 12 and Second Buffer Layer 14

The first buffer layer 12 and the second buffer layer 14 are sandwiched between the active layer and the first electrode or the second electrode. When these layers are present, one of these layers functions as a hole transport layer, and the other functions as an electron transport layer. In order for the semiconductor element to achieve more excellent conversion efficiency, it is preferable to include these layers, but these layers are not necessarily essential in the embodiment, and either or both of these layers may not be included. In addition, both or one of the first buffer layer 12 and the second buffer layer 14 may have a structure in which different materials are laminated.

The electron transport layer has a function of efficiently transporting electrons. When the buffer layer functions as an electron transport layer, the layer preferably contains either a halogen compound or a metal oxide. Preferable examples of the halogen compound include LiF, LiCl, LiBr, LiI, NaF, NaCl, NaBr, NaI, KF, KCl, KBr, KI, and CsF. Among them, LiF is particularly preferable.

Preferable examples of the element constituting the metal oxide include titanium, molybdenum, vanadium, zinc, nickel, lithium, potassium, cesium, aluminum, niobium, tin, and barium. A composite oxide containing a plurality of metal elements is also preferable. For example, zinc oxide (AZO) doped with aluminum, titanium oxide doped with niobium, and the like are preferable. In these metal oxides, titanium oxide is more preferable. The titanium oxide is preferably amorphous titanium oxide obtained by hydrolyzing a titanium alkoxide by a sol-gel method.

For the electron transport layer, an inorganic material such as metallic calcium can also be used.

When the electron transport layer is provided in the photoelectric conversion element according to the embodiment, a thickness of the electron transport layer is preferably 20 nm or less. This is because a film resistance of the electron transport layer can be lowered and conversion efficiency can be enhanced. Meanwhile, the thickness of the electron transport layer can be 5 nm or more. By providing the electron transport layer and setting the thickness thereof to a certain value or more, hole blocking effects can be sufficiently exhibited, and it is possible to prevent generated excitons from being deactivated before releasing electrons and holes. As a result, the current can be efficiently extracted.

An n-type organic semiconductor is preferred but not limited to fullerene and a derivative thereof. Specific examples thereof include derivatives having C60, C70, C76, C78, C84, or the like as a basic skeleton. In a fullerene derivative, a carbon atom in a fullerene skeleton may be modified with an arbitrary functional group, and the functional groups may be bonded to each other to form a ring. The fullerene derivative includes fullerene-bonded polymers. The fullerene derivative is preferably a fullerene derivative having a functional group having high affinity for a solvent and having high solubility in a solvent.

Examples of the functional group in the fullerene derivative include a hydrogen atom; a hydroxy group; a halogen atom such as a fluorine atom or a chlorine atom; an alkyl group such as a methyl group or an ethyl group; an alkenyl group such as a vinyl group; a cyano group; an alkoxy group such as a methoxy group or an ethoxy group; an aromatic hydrocarbon group such as a phenyl group or a naphthyl group, an aromatic heterocyclic group such as a thienyl group or a pyridyl group, and the like. Specific examples thereof include a hydrogenated fullerene such as C60H36 and C70H36, an oxide fullerene such as C60 and C70, and a fullerene metal complex.

Among the above, it is particularly preferable to use [60]PCBM([6,6]-phenyl C61 butyric acid methyl ester) or [70]PCBM([6,6]-phenyl C71 butyric acid methyl ester) as the fullerene derivative.

In addition, as the n-type organic semiconductor, a low molecular weight compound that can be deposited by vapor deposition can be used. The low molecular weight compound referred to herein is one in which a number average molecular weight Mn and a weight average molecular weight Mw are the same. Any one of them is 10,000 or less. BCP(bathocuproine), Bphen(4,7-diphenyl-1,10phenanthroline), TpPyPB(1,3,5-tri(p-pyridine-3yl-phenyl)benzene), DPPS(diphenyl bis(4-pyridine-3yl)phenyl)silane) are more preferable.

The hole transport layer has a function of efficiently transporting holes. When the buffer layer functions as a hole transport layer, the layer can contain a p-type organic semiconductor material or an n-type organic semiconductor material. The p-type organic semiconductor material and the n-type organic semiconductor material mentioned herein are materials that can function as an electron donor material or an electron acceptor material when a heterojunction or a bulk heterojunction is formed.

The p-type organic semiconductor can be used as a material of the hole transport layer. The p-type organic semiconductor preferably contains, for example, a copolymer composed of a donor unit and an acceptor unit. As the donor unit, fluorene, thiophene, or the like can be used. As the acceptor unit, benzothiadiazole or the like can be used. Specifically, polythiophene and derivatives thereof, polypyrrole and derivatives thereof, pyrazoline derivatives, arylamine derivatives, stilbene derivatives, triphenyldiamine derivatives, oligothiophene and derivatives thereof, polyvinylcarbazole and derivatives thereof, polysilane and derivatives thereof, polysiloxane derivatives having an aromatic amine in a side chain or a main chain, polyaniline and derivatives thereof, phthalocyanine derivatives, porphyrin and derivatives thereof, polyphenylenevinylene and derivatives thereof, polythienylenevinylene and derivatives thereof, benzodithiophene derivatives, thieno[3,2-b]thiophene derivatives, and the like can be used. For the hole transport layer, these materials may be used in combination, or a copolymer composed of a copolymer constituting these materials may be used. Among them, polythiophene and derivatives thereof are preferable because they have excellent stereoregularity and have relatively high solubility in a solvent.

In addition, as a material of the hole transport layer, a derivative such as poly[N-9′-heptadecanyl-2,7-carbazole-alto-5,5-(4′,7′-di-2-thienyl-2′,1′,3′-benzothiadiazole)] (hereinafter, sometimes referred to as PCDTBT), which is a copolymer containing carbazole, benzothiadiazole, and thiophene, may be used. Furthermore, a copolymer of a benzodithiophene (BDT) derivative and a thieno[3,2-b]thiophene derivative is also preferable. For example, poly[[4,8-bis[(2-ethylhexyl)oxy]benzo[1,2-b:4,5-b]dithiophene-2,6-diyl][3-fluoro-2-[(2-ethylhexyl)carbonyl]thieno[3,4-b]thiophenediyl]] (hereinafter sometimes referred to as PTB7), PTB7-Th (sometimes referred to as PCE 10, or PBDTTT-EFT) in which a thienyl group having a weaker electron donating property than the alkoxy group of PTB7 is introduced, and the like are also preferable. Furthermore, a metal oxide can also be used as a material of the hole transport layer. Preferable examples of the metal oxide include titanium oxide, molybdenum oxide, vanadium oxide, zinc oxide, nickel oxide, lithium oxide, calcium oxide, cesium oxide, and aluminum oxide. These materials have the advantage of being inexpensive. Furthermore, as the material of the hole transport layer, a thiocyanate such as copper thiocyanate may be used.

In addition, a dopant can be used for a transport material such as spiro-OMeTAD and the aforesaid p-type organic semiconductor. As the dopant, oxygen, 4-tert-butylpyridine, lithium-bis(trifluoromethanesulfonyl)imide(Li-TFSI), acetonitrile, tris[2-(1H -pyrazole-1yl)pyridine]cobalt(III)tris(hexafluorophosphate) salt (commercially available under the trade name of “FK102”), tris[2-(1H-pyrazole-1yl)pyrimidine]cobalt(III)tris[bis(trisfluoromethylsulfonyl)imide](MY11), or the like can be used.

As the hole transport layer, a conductive polymer compound such as polyethylene dioxythiophene can be used. As such a conductive polymer compound, those listed in the electrode section can be used. Also in the hole transport layer, it is possible to combine another material with a polythiophene polymer such as PEDOT to adjust a material having an appropriate work function as hole transport or the like. Here, it is preferable to adjust the work function of the hole transport layer to be lower than a valence band of the active layer.

The second buffer layer is preferably an electron transport layer, Furthermore, the oxide layer is preferably an oxide layer of a metal selected from the group consisting of zinc, titanium, aluminum, and tungsten. The oxide layer may be a composite oxide layer containing two or more kinds of metals. This is because the electrical conductivity is improved by the light soaking effect, and thus the power generated in the active layer can be efficiently extracted. By disposing this layer on the second electrode side of the active layer, light soaking can be performed by light passing through the barrier layer and the second buffer layer, particularly UV light. In addition, even when a material that blocks UV light is used for the substrate like a polymer substrate, it has a feature that light soaking can be performed by irradiating UV light from the second electrode side. When electrical conductivity can be maintained for a long period of time, it can also be concealed with a non-permeable or low permeable material after the light soaking.

The second buffer layer preferably has a structure in which a plurality of layers are laminated as illustrated in FIG. 1. In such a case, a layer adjacent to the barrier layer is preferably a layer containing the metal oxide. With such a structure, when the barrier layer is formed by sputtering, the active layer and the second buffer layer adjacent to the active layer are less likely to be damaged by sputtering.

The second buffer layer preferably has a structure including voids. More specifically, a buffer layer having a structure including a deposit of nanoparticles and having voids between the nanoparticles, a structure including a bonded body of nanoparticles and having voids between the bonded nanoparticles, and the like is preferable. The barrier layer is provided between the second electrode and the second buffer layer in order to suppress the corrosion of the second electrode due to the substance penetrating from another layer. Meanwhile, the material constituting the perovskite layer tends to have a high vapor pressure at a high temperature. Therefore, a halogen gas, a hydrogen halide gas, and a methylammoniurn gas are easily generated in the perovskite layer. When these gases are confined by the barrier layer, the element may be damaged from the inside due to an increase in internal pressure. In such a case, peeling of a layer interface is particularly likely to occur. Therefore, since the second buffer layer contains voids, the increase in the internal pressure is alleviated, and high durability can be provided.

### Barrier Layer

The semiconductor element according to the embodiment preferably further includes the barrier layer between the active layer and the second electrode. The barrier layer is preferably made of a metal oxide having light transmissivity.

By means of this barrier layer, the second electrode, that is, the metal layer, is structurally isolated from the active layer. As a result, the second electrode is less likely to be corroded by a substance penetrating from another layer. In particular, when the active layer is a perovskite semiconductor, it is known that halogen ions such as iodine and bromine diffuse from the active layer into the element, and components reaching the metal electrode cause corrosion. It is believed that the barrier layer can efficiently block diffusion of such substances. When the semiconductor element includes the second buffer layer, it is preferable to provide the barrier layer between the second buffer layer and the second electrode. This is because with such a layer configuration, diffusion of substances released from the second buffer layer can also be blocked.

The barrier layer preferably contains indium tin oxide (ITO), indium zinc oxide (IZO), fluorine-doped tin oxide (FTC)), and aluminum-doped zinc oxide (AZO). The thickness of the barrier layer is preferably 5 to 100 nm, and more preferably 10 to 70 nm. With such a structure, in a case where light is emitted from the second electrode side, since the light is transmitted to the active layer and the second buffer layer, in particular, by emitting UV light from the second electrode side, electrical conductivity is improved by the light soaking effect, and power generated by the active layer can be efficiently extracted.

The material of the barrier layer can be the same as that of a metal oxide generally used for an electrode, but the properties of the barrier layer are preferably different from those of a general metal oxide layer utilized for an electrode. That is, the barrier layer is not characterized only by a simple constituent material, but also has a feature in its crystallinity or oxygen content. Qualitatively, its crystallinity or oxygen content is lower than a metal oxide layer formed by sputtering, which is typically utilized as an electrode. Specifically, an oxygen content of the barrier layer is preferably 62.1 to 62.3 atom %. The oxygen content is higher than that of the metal oxide layer used for the buffer layer. In general, when a metal oxide layer is used as a buffer layer, a coating method is employed so as not to damage an adjacent active layer when the buffer layer is formed. In this case, the density of the metal oxide layer to be formed is low, for example, the density is 1.2 to 5, but the density of the barrier layer in the embodiment is 7 or more. In the configuration of the present embodiment, when the barrier layer is located on an opposite side of a light receiving surface, there is no concern that the active layer and the buffer layer are decomposed even when the barrier layer is a metal oxide having a photocatalytic action. Here, the light receiving surface refers to a surface on which the element mainly receives light.

Whether the barrier layer functions can be confirmed by elemental analysis in a cross-sectional direction after a durability test. Time-of-flight secondary ion mass spectrometry (TOF-SIMS) or the like can be used. At least two or more peaks of the substance causing the deterioration of the second electrode are separately detected so as to sandwich the peak position of the material indicating the barrier layer, and a peak area on the second electrode side is smaller than the total area of the other peaks. In the case of complete barrier, the peak on the second electrode side cannot be confirmed. The peak on the second electrode side is preferably so small that it cannot be confirmed, but the durability is greatly improved only by shielding the most part with the barrier layer. That is, even when the degraded substance that has rarely passed through the barrier layer degrades a part of the electrode of the second electrode, the characteristics such as the electrical resistance of the second electrode are not significantly changed, so that a significant change does not appear in the conversion efficiency of the solar cell. Meanwhile, when the second electrode and the degraded substance react with each other without the barrier layer, the characteristics such as the electrical resistance of the second electrode are greatly changed, so that the conversion efficiency of the solar cell is greatly changed (the conversion efficiency is lowered). Preferably, the peak area on the second electrode side is 0.007 with respect to the total area of the other peaks.

Such a barrier layer can be formed, for example, by sputtering under specific conditions (details will be described later).

By using the second electrode containing aluminum or silver in combination with the barrier layer, it is not necessary to use gold which is generally used for improving the durability of the semiconductor element as an electrode material. The cost of a gold electrode is approximately 15,000 yen/m², whereas the costs of ITO, aluminum, and silver are 100 to 1000 yen/m², about 1 yen/m², and about 200 yen/m², respectively. That is, it is possible to provide a photoelectric conversion element having durability at low cost.

The structure of the photoelectric conversion element manufactured by the method of the present embodiment has been described above. Here, the active layer including, for example, a perovskite semiconductor can also function as a light emitting layer. Therefore, the semiconductor element having the structure according to the embodiment functions not only as a photoelectric conversion element but also as a light-emitting element.

### Method for Manufacturing Photoelectric Conversion Element

The photoelectric conversion element according to the embodiment can be manufactured by the same method as a general semiconductor element except for controlling the Warburg coefficient of the active layer. The substrate, the first electrode, the second electrode, the active layer, the buffer layer and the barrier layer to be formed as necessary, and the like are not limited in material and manufacturing method. Hereinafter, a method for manufacturing the photoelectric conversion element according to the embodiment will be described.

First, the first electrode is formed on the base material. The electrode can be formed by any method. For example, a method selected from a vacuum vapor deposition method, a sputtering method, an ion plating method, a plating method, a coating method, and the like is used.

Next, the buffer layer or an underlayer is formed as necessary. The buffer layer can also be formed by a method selected from a vacuum vapor deposition method, a sputtering method, an ion plating method, a plating method, a coating method, and the like. The underlayer (to be described in detail later) is usually formed by a coating method.

Next, the active layer is formed directly on the electrode or on the electrode via the buffer layer or the underlayer.

In the method according to embodiments, the active layer can be formed by any method. However, it is advantageous to form the active layer by a coating method from the viewpoint of cost. For example, the active layer containing the perovskite semiconductor can be formed by a coating method, which is preferable. That is, a coating liquid containing a precursor compound having the perovskite structure and an organic solvent capable of dissolving the precursor compound is applied onto the first electrode or the first buffer layer to form a coating film.

As the solvent used for the coating liquid, for example, N,N-dimethylformamide (DMF), γ-butyrolactone, dimethylsulfoxide (DMSO), or the like is used. The solvent is not limited as long as it can dissolve the material, and may be mixed. The coating liquid may be obtained by dissolving a plurality of raw materials forming the perovskite structure in one solution. In addition, a plurality of raw materials forming the perovskite structure may be individually adjusted into solutions and sequentially applied by a spin coater, a slit coater, a bar coater, a dip coater, or the like.

The coating liquid may further contain an additive. As the additive, 1,8-diiodooctane (DIO) and N-cyclohexyl-2 pyrrolid one (CHP) is preferable.

In general, it is known that when a mesoporous structure is included in an element structure, leakage current between electrodes is suppressed even when pinholes, cracks, voids, or the like are generated in the active layer. When the element structure does not have the mesoporous structure, it is difficult to obtain such an effect. However, when the coating liquid contains a plurality of raw materials having the perovskite structure in the embodiment, volume shrinkage during active layer formation is small, so that a film having fewer pinholes, cracks, and voids is easily obtained. Furthermore, when a solution containing methyl ammonium iodide (MAI), a metal halogen compound, and the like is applied after the coating liquid is applied, a reaction with an unreacted metal halogen compound proceeds, and a film having fewer pinholes, cracks, and voids is easily obtained. Therefore, it is preferable to apply a solution containing MAI to the surface of the active layer after the coating liquid is applied.

The coating liquid containing the precursor of the perovskite structure may be applied twice or more. In such a case, since the active layer formed by the first application tends to be a lattice mismatch layer, it is preferable that the active layer is applied so as to have a relatively thin thickness. Specifically, the second and subsequent coating conditions are preferably conditions for reducing the film thickness, such as a relatively high rotation speed of the spin coater, a relatively narrow slit width of the slit coater or the bar coater, a relatively high pulling speed of the dip coater, and a relatively low solute concentration in the coating solution.

### Annealing Treatment

In order to form an active layer having a specific Warburg coefficient in the photoelectric conversion element according to the embodiment, it is preferable to quickly form a perovskite structure having few lattice defects in the applied coating film. For this reason, it is preferable to perform an appropriate annealing treatment after the application. When the conditions for the annealing treatment are not appropriate, distortion occurs in the perovskite structure, lattice defects occur, and the Warburg coefficient tends to decrease. Specifically, an annealing temperature is preferably 20 to 200° C., more preferably 100 to 150° C., and an annealing time is preferably 10 to 60 minutes, more preferably 10 to 20 minutes.

### Gas Blowing

In order to form the active layer having the specific Warburg coefficient, a gas can also be blown onto the coating film of the perovskite precursor.

The type of gas is not particularly limited. For example, helium, neon, or argon classified as nitrogen or rare gas is preferably used. Air, oxygen, carbon dioxide, and the like can also be used. These gases may be used alone or in combination. Nitrogen gas is preferable because it is inexpensive and can be used separately from the atmosphere. A moisture concentration of the gas is generally 50% or less, preferably 4% or less. Meanwhile, a lower limit value of moisture is preferably 10 ppm.

The temperature of the gas is preferably 30° C. or lower. The higher the temperature is, the higher the solubility of the raw material of the perovskite structure contained in the coating liquid is, so that the formation of the perovskite structure is inhibited.

Meanwhile, the substrate temperature is preferably lower than the gas temperature. For example, the temperature is preferably 20° C. or lower; and more preferably 15° C. or lower.

When the gas blowing is performed, formation of a perovskite structure having few lattice defects can be promoted, and the active layer having a high Warburg coefficient can be formed. This mechanism has not been clarified in detail, but it is considered that the spontaneous perovskite structure crystallization reaction is promoted, and lattice defects are less likely to occur. It is considered that the elimination of the solvent also proceeds in the process of forming the perovskite structure. The formation of pinholes, cracks, or voids is suppressed since the perovskite structure forming reaction proceeds even without applying heat due to the blowing of the gas. In addition, by not applying heat, rapid drying of the coating film surface is suppressed, and a stress difference between the coating film surface and the inside is suppressed. Therefore, the smoothness of the surface of the active layer to be formed is increased, leading to improvement of the fill factor and improvement of the life.

The gas is preferably blown before the formation reaction of the perovskite structure is completed in the coating liquid. In addition, it is preferable to start the blowing of gas promptly after forming a liquid film of the coating liquid. Specifically, it is preferably within 10 seconds, and more preferably within 1 second. As start of the gas blowing is earlier, the perovskite structure is uniformly formed, and element performance is improved. In the process of drying the coating liquid, single crystals such as MAI and lead iodide may also grow as raw materials at the same time as the formation of the perovskite structure. It is possible to efficiently grow the perovskite structure as the perovskite structure is quickly dried from the state of being dissolved and dispersed in the coating liquid. The method according to the embodiment is effective when a perovskite structure is formed on an organic film or an oxide having a large lattice mismatch.

The progress of the reaction can be observed by an absorption spectrum of the coating liquid or the coating film. That is, the light transmittance decreases with the formation of the perovskite structure. Therefore, when visually observed, it can be seen that the coating film turns brown as the reaction proceeds. In order to quantitatively observe such a color change, an absorption spectrum of the coating film is measured. In the case of performing such an observation, it is preferable to measure an absorption spectrum of a wavelength that is hardly affected by absorption of the raw material contained in the coating liquid and in which absorption by the perovskite structure is easily observed. Specifically, it is preferable to measure an absorption spectrum in a wavelength region of 700 to 800 nm. The measurement of the absorption spectrum does not need to be performed for the entire region, and an absorption spectrum at a specific wavelength, for example, 800 nm may be observed. For example, the completion of the formation reaction can be a time point at which there is no change in the absorption spectrum at 700 to 800 nm.

Although the change in the absorption spectrum is not directly associated with the Warburg coefficient, the completion time of the formation reaction of the perovskite structure and the Warburg coefficient have a correlation. That is, by adjusting the reaction to proceed at an appropriate speed, the occurrence of lattice defects can be suppressed, and the Warburg coefficient can be increased. Since it also depends on a gas blowing device, the type and flow velocity of the gas to be blown, the environmental temperature, and the like, the optimum reaction time changes, but under a specific device and a specific environment, the Warburg coefficient when the reaction time is changed is measured in the dark to create a calibration curve, and an active layer having a desired Warburg coefficient can be formed based on the calibration curve. In addition, the calibration curve is created by measuring a change in the Warburg coefficient when the annealing temperature, the annealing time, a gas blowing time, a gas blowing speed, and the like are changed, and an element having a desired Warburg coefficient can be formed based on the calibration curve.

The absorption spectrum can be measured by transmitted light when the substrate, the electrode, and the like are transparent at the stage of applying the coating liquid. Meanwhile, when there is not sufficient transparency, measurement can be performed by observing reflected light on the surface of the coating film.

When the coating liquid containing the raw material for forming the perovskite structure is in contact with a layer containing an organic material, for example, the first electrode 11, the first buffer layer 12, the second buffer layer 14, the second electrode 15, or the like, or the later-described underlayer, the gas blowing time is preferably 45 seconds or more, and more preferably 120 seconds or more.

It is preferable that the gas is blown at a high flow velocity on the applied surface. That is, generally, the gas is blown through the nozzle, but the tip of the nozzle is preferably directed to the application surface, and the tip of the nozzle is preferably close to the application surface.

For forming the active layer accompanied by the gas blowing, for example, a semiconductor element manufacturing apparatus illustrated in the schematic diagram of FIG. 2 can also be used.

The apparatus includes:

(i) a nozzle 21 for blowing a gas onto a coating film 24 applied on an electrode or the like,

(ii) a measurement unit 22 that observes a state of a portion 24a to which the gas is blown, particularly the progress of the perovskite structure forming reaction, and

(iii) a control unit 23 that controls a position at which the nozzle blows a gas or a gas blowing amount according to information observed in the measurement unit.

As the nozzle 21, a nozzle having an arbitrary shape can be used, but it is preferable that the nozzle has a shape capable of appropriately controlling a flow velocity of the gas flowing through the coating film surface. The faster the gas flow flowing to the coating film surface, the faster the progress of the formation reaction of the perovskite structure tends to be, which is preferable. Meanwhile, in order to prevent fluctuation of the coating film surface due to the gas flow, the gas flow velocity is preferably low.

Specific examples of the spray nozzle include a straight spray nozzle, a conical spray nozzle, and a fan-shaped spray nozzle.

In order to increase the flow velocity of the gas on the coating film surface, a tip of the nozzle is preferably directed to the coating surface, and the tip of the nozzle is preferably dose to the coating surface.

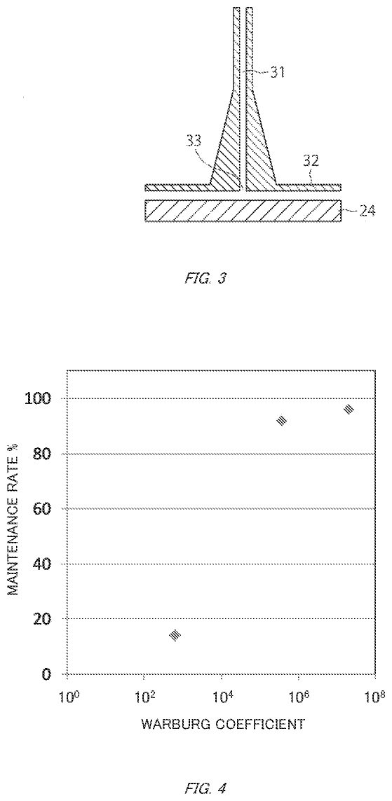

In order to obtain a more preferable effect, the nozzle preferably has a pipe 31 and a flange 32 (gas flow guiding unit) as illustrated in the schematic cross-sectional view of FIG. 3. With the presence of the flange 32, a gas passage is formed between the flange 32 and the surface of the coating film 24, and a sufficiently fast flow velocity of the gas can be secured even when the gas passage is far from a gas outlet 33. Therefore, it is preferable because the speed of gas flow over the entire application surface can be managed with a limited amount of gas, and the effect of the embodiment can be obtained over a wide range of the application surface. A plurality of nozzle portions may be provided.

In addition, the measurement unit 22 observes the state of the portion 24a to which the gas is blown. The measurement unit particularly observes the progress of the perovskite structure forming reaction. That is, although the reaction is promoted by the gas blowing, the gas blowing is not necessary after completion of the reaction. Such information regarding the progress is sent to the control unit 23, and the control unit 23 changes the portion to be blown with the gas to the portion where the reaction is not in progress by stopping the blowing of the gas from the nozzle, driving the position of the nozzle, or driving or rotating the position of the substrate according to the information. Since the progress of the reaction can be observed by the absorption spectrum as described above, it is preferable that an absorption spectrum measuring device is incorporated in the measurement unit 22. The measurement unit 22 is preferably integrated with the nozzle 21 to simplify the structure in order to observe the state of the portion to which the gas is blown by the nozzle. In addition to the progress of the reaction, the measurement unit 22 may simultaneously measure the thickness of the coating film, the smoothness of the surface, and the like.

It is preferable that the gas blowing is stopped after the perovskite structure forming reaction is completed, but the gas spraying may be stopped before the reaction is completely completed in order to improve productivity.

That is, when the progress of the reaction is 70% or more, since the basic configuration of the perovskite structure is formed, the influence on the uniformity of the formed perovskite structure is small even when the gas blowing is stopped. Therefore, when the progress of the reaction of the portion to which the gas is blown becomes equal to or more than a certain level, the gas blowing portion may be controlled to be scanned so as to change the gas blowing portion.

The device for blowing a gas to the coating film may further include a substrate fixing unit for installing a substrate and an application unit for applying the coating liquid.

After blowing the gas, the coating liquid containing the precursor of the perovskite structure may be further applied one or more times. The coating application can be performed by a spin coater, a slit coater, a bar coater, a dip coater, or the like. In such a case, since the active layer formed by the first application tends to be a lattice mismatch layer, it is preferable that the active layer is applied so as to have a relatively thin thickness. Specifically, it is preferable that the conditions are set such that the film thickness is reduced, for example, a rotation speed of the spin coater is relatively fast, a slit width of the slit coater or the bar coater is relatively narrow, a pulling speed of the dip coater is relatively fast, and a solute concentration in the coating solution is relatively thin.

In a conventional method called a two-step method, sequential deposition, or the like, gas is blown after completion of the perovskite structure forming reaction, that is, after sufficient color development occurs by the reaction, but this is performed simply for drying the solvent component. The gas blowing is effective in an element including a mesoporous structure or an underlayer such as titanium oxide or aluminum oxide because the perovskite structure is easily crystallized by these elements, but the gas sprays are less effective in the formation reaction of the perovskite structure on other organic films or oxides having a large lattice mismatch. When the perovskite structure is formed on the organic film or the oxide having a large lattice mismatch, as described in the embodiment, the formation reaction of the perovskite structure is promoted by blowing the gas before the completion of the perovskite formation reaction, so that the suppression of the defect structure such as the pinhole, the crack, and the void can be realized, and the Warburg coefficient can be increased.

### Underlayer

Prior to forming the active layer, the underlayer can be formed in addition to or instead of the first or second buffer layer.

The underlayer is preferably composed of a low molecular weight compound. The low molecular weight compound referred to herein is one in which the number average molecular weight Mn and the weight average molecular weight Mw coincide with each other; and is 10,000 or less. For example, a compound containing a low molecular weight compound such as an organic sulfur molecule, an organic selenium tellurium molecule, a nitrile compound, a monoalkylsilane, a carboxylic acid, a phosphoric acid, a phosphoric acid ester, an organic silane molecule, an unsaturated hydrocarbon, an alcohol, an aldehyde, an alkyl bromide, a diazo compound, or an alkyl iodide is used. For example, 4-fluorobenzoic acid (FBA) is preferred.

The underlayer can be formed by applying a solution containing a low molecular weight compound as described above and drying the solution. By forming the underlayer, it is possible to obtain effects such as improving the collection efficiency of carriers from the perovskite layer to the electrode by utilizing the vacuum level shift by the dipole, improving the crystallinity of the perovskite layer, suppressing the generation of pinholes in the perovskite layer, and increasing the light transmission amount on the light receiving surface side. As a result, there are effects of increasing the current density and improving the fill factor, and the photoelectric conversion efficiency and the light emission efficiency can be improved. In particular, when a perovskite structure is formed on a buffer layer or an electrode of a crystal system having a large lattice mismatch other than titanium oxide and aluminum oxide, by providing an underlayer, the underlayer itself can serve as a stress relieving layer, or a part of the perovskite structure close to the underlayer can have a stress relieving function. The underlayer not only improves the crystallinity of the perovskite layer, but also relaxes internal stress associated with crystal growth, so that generation of pinholes can be suppressed and good interface bonding can be realized.

### Method for Forming Barrier Layer

The barrier layer can be formed by sputtering, vacuum deposition, physical vapor deposition (PVD), chemical vapor deposition (CVD), coating, spin coating, spraying, or the like. However, any method may damage the photoelectric conversion layer and the buffer layer. When the damage occurs, the conversion efficiency may decrease or become unstable in the completed photoelectric conversion element. As causes of the damage, oxygen, heat, UV, deterioration causing substances (ions, compounds, gases, or the like), and the like are mentioned, and in order to obtain a semiconductor element having excellent characteristics, it is important to exclude these.

In the embodiment, the barrier layer is preferably formed by sputtering. In the case of sputtering,
(1) reverse sputtering by incident ions such as argon reflected from a target,
(2) incidence of γ electrons generated with a discharge phenomenon,
(3) incidence of ultraviolet rays radiated from oxygen introduced as a reaction gas, and
(4) a reaction with a radical species such as an oxygen radical generated from a reaction gas
may be a major source of damage. (1) and (2) can be suppressed by minimizing the amount of power to be supplied. Specifically, the amount of power to be supplied is preferably 1200 W or less. More preferably, a DC power supply is 200 to 300 W. In particular, a current amount may be set to be small, specifically, less than 1 A, such as a voltage of 400 V and a current of 0.6 A. Since the amount of reaction gas such as oxygen is small, oxygen supply from the target can be increased.

In addition, it is possible to suppress damage due to γ rays by confining γ electrons with magnetic lines as in magnetron sputtering or a counter target. It is possible to suppress (3) and (4) by not using the reaction gas or reducing the amount of the reaction gas. The barrier layer obtained as a result has a feature of having a low oxygen content ratio in terms of elemental ratio because of a small amount of reaction gas. Specifically, the oxygen content contained in the barrier layer is preferably 62.1 to 62.3 atom %. Such an oxygen content is lower than that of the metal oxide film used as an electrode on the light receiving surface side. Therefore, when ITO is used as the first electrode, the oxygen ratio of the barrier layer is smaller than the oxygen ratio in the element ratio of the first electrode. Since the electrical resistance and the transmittance tend to deteriorate as the oxygen ratio decreases, the film thickness of the barrier layer is preferably thin. The thickness is 100 nm or less, more preferably 10 to 50 nm. Since a film formation time becomes longer and a film formation cost per unit area increases as the film thickness increases, it is advantageous in providing an inexpensive durable element that a thin film can be used.

### EXAMPLES

Conventionally, evaluation of an element using the perovskite structure has been performed for an element having a small power generation area of about 2 mm square. Since the element using the perovskite structure is produced by film formation accompanied by crystal growth, internal stress due to volume shrinkage or the like is generated, which causes problems such as generation of pinholes and delamination. Therefore, it was difficult to prepare a layer structure having few structural defects. For this reason, in the field of mass production, the reproducibility of the conversion efficiency was low and the variation was large. Therefore, when there are few defects accidentally in a part, specifically high conversion efficiency may be obtained, but it is difficult to uniformly obtain high conversion efficiency in a wide range.

Meanwhile, for practical use, it is necessary to manufacture an element capable of realizing high efficiency in a wider range. Therefore, in the following Examples, an element having a power generation area of 1 cm square was manufactured and subjected to comparative examination. The solar cell prepared by coating is usually formed by arranging strip-shaped cells having a width of about 1 cm in a series structure. Therefore, an element having a power generation area of 1 cm square has an appropriate size to be an index of actual module performance.

### Comparative Example 1

An ITO film was formed as a first electrode on a glass substrate. A first buffer layer (hole transport layer) was formed thereon by spin coating, and then a perovskite layer was formed as an active layer (photoelectric conversion layer). The perovskite layer was formed by referring to the two-step method of Non Patent Literature 1. First, a DMF solution containing DMSO in an equimolar amount or more with lead iodide (PbI₂) was spin-coated in a glove box under a nitrogen atmosphere, and then a solution of methyl ammonium iodide (MAI) in isopropyl alcohol (IPA) was spin-coated. When a DMF solution containing DMSO was applied by spin coating, a gas was blown onto the surface of the formed coating film. This was annealed at 100° C. for 10 minutes. The perovskite structure of MAIPbI₃ was formed. Next, as a second buffer layer (electron transport layer), a laminate spin-coated with PCBM dissolved in dichlorobenzene was prepared. The thickness of the PCBM is 100 nm. In the present Example, an AZO nanoparticle dispersion (nano-grade, N-20X) was further applied as an AZO layer by spin coating, and then annealed at 75° C. The thickness was about 50 nm. This was introduced into a sputtering apparatus, and an ITO film was formed as a barrier layer by sputtering. A sputtering pressure was set to 2.7 mTorr, input power was set to 0.9 kW, and a film formation speed was set to 0.408 angs/second. The sputtering was performed in argon gas. A reaction gas such as oxygen was not introduced. The thickness was about 43 nm. Finally, silver was deposited as a second electrode in a thickness of about 60 nm by a vacuum vapor deposition apparatus. Finally, the glass plate was bonded and sealed with a UV curable resin to obtain a photoelectric conversion element of Comparative Example 1. The Warburg coefficient of this photoelectric conversion element was 5,240.

### Examples 1 and 2

The annealing conditions after the application of the perovskite layer were changed to 125° C. for 30 minutes (Example 1) or 135° C. for 30 minutes (Example 2) to obtain the photoelectric conversion elements of Examples 1 and 2. Warburg coefficients of these photoelectric conversion elements were 27,500 and 8.52 million.

The obtained photoelectric conversion element was subjected to a durability test in accordance with JIS 8938. First, the conversion efficiency of each element was measured. Next, the conversion efficiency was measured after each element was stored in an atmosphere at 85° C. for 1000 hours. The ratio of the conversion efficiency after storage to the initial conversion efficiency was taken as a maintenance rate. The obtained results are as illustrated in FIG. 2. A horizontal axis illustrates the Warburg coefficient of the element before the durability test. As can be seen from FIG. 2, when the Warburg coefficient was 25,000 or more, the maintenance rate was 90% or more. Below this, the maintenance rate rapidly decreased.

### REFERENCE SIGNS LIST

10 photoelectric conversion element
11 first electrode
12 first buffer layer
13 active layer (photoelectric conversion layer)
14 second buffer layer
14A active layer-side buffer layer
14B second electrode-side buffer layer
15 barrier layer
16 second electrode
17 substrate
21 nozzle
22 measurement unlit
23 control unit
24 coating film
31 pipe
32 flange
33 gas outlet

1. A photoelectric conversion element comprising:
a first electrode;
an active layer having a perovskite structure containing a halogen ion; and
a second electrode having light transmissivity,
wherein a Warburg coefficient calculated from a Warburg impedance W (Ωs^{-1/2}) determined when an impedance spectrum measured by an AC impedance spectroscopy method fitted with an equivalent circuit represented by the following Equation (1) is 25,000 or more.

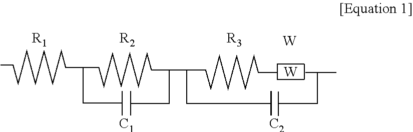

2. The photoelectric conversion element according to claim 1, wherein the second electrode has a laminated structure of a light transmitting oxide layer and a metal layer.

3. The photoelectric conversion element according to claim 2, wherein the light transmitting oxide is selected from the group consisting of indium tin oxide, indium zinc oxide, fluorine-doped tin oxide, and aluminum-doped zinc oxide,

4. The photoelectric conversion element according to claim 2, wherein the metal layer contains a metal selected from the group consisting of aluminum and silver.

5. The photoelectric conversion element according to claim 2, wherein the metal layer has a uniform thickness.

6. The photoelectric conversion element according to claim 1, wherein the perovskite structure is represented by the following Equation (1):
ABX₃ (1)
(wherein
A is a primary ammonium ion,
B is a divalent metal ion, and
X is a halogen ion).

7. The photoelectric conversion element according to claim 1, further comprising a barrier layer that blocks diffusion of the halogen ion between the active layer and the second electrode.

8. The photoelectric conversion element according to claim 7, wherein the barrier layer is made of a metal oxide having light transmissivity.

9. A method for manufacturing the photoelectric conversion element according to claim 1, the method comprising a step of forming the active layer by forming a perovskite structure by subjecting a coating film of a solution containing a precursor of the perovskite structure to an annealing treatment or a gas blowing treatment.

10. The method for manufacturing the photoelectric conversion element according to claim 9, wherein the annealing treatment is performed at 100 to 150° C. for 20 to 30 minutes.

11. The method for manufacturing the photoelectric conversion element according to claim 9, wherein the gas blowing is started within 10 seconds after the coating film is applied.
